(19) United States
(12) Patent Application Publication
(10) Pub. No.: US 2025/0112441 A1
(43) Pub. Date: Apr. 3, 2025

(54) SUBMARINE APPARATUS, SUBMARINE CABLE SYSTEM, AND NON-TRANSITORY COMPUTER-READABLE MEDIUM

(71) Applicant: NEC Corporation, Minato-ku, Tokyo (JP)

(72) Inventor: Narihiro Arai, Tokyo (JP)

(73) Assignee: NEC Corporation, Minato-ku, Tokyo (JP)

(21) Appl. No.: 18/729,139

(22) PCT Filed: Feb. 1, 2022
(86) PCT No.: PCT/JP2022/003771

§ 371 Date: Jul. 15, 2024

(51) Int. Cl. H01S 5/06

(52) U.S. Cl. CPC H01S 5/0612

(57) ABSTRACT

Provided are a submarine apparatus, a submarine cable system, a method for controlling the submarine apparatus, and a non-transitory computer-readable medium that can be stably operated. The submarine apparatus includes a laser element configured to generate an optical signal to be used in a case of responding to a remote control signal received from a land apparatus disposed on land via a cable, and a temperature adjustment unit configured to adjust a temperature of the laser element, and is disposed on the seabed.

### TECHNICAL FIELD

The present disclosure relates to a submarine apparatus, a submarine cable system, a method for controlling the submarine apparatus, and a non-transitory computer-readable medium.

### BACKGROUND ART

Patent Literature 1 discloses that power is supplied from a constant current supply apparatus to a submarine apparatus constituting a submarine cable system. The constant current supply apparatus of Patent Literature 1 uses a constant current power supply system supplying power to a submarine apparatus by controlling a drive current flowing through n sets of drive elements.

Patent Literature 2 discloses that power is supplied from a drive voltage generation means to a submarine apparatus constituting a submarine cable system. The drive voltage generation means of Patent Literature 2 generates a voltage in response to a current flowing through n pieces of Zener diode groups.

Patent Literature 3 describes that power is supplied from an energization switching unit to a submarine apparatus constituting a submarine cable system. In order to suppress occurrence of a failure, the energization switching unit of Patent Literature 3 switches supply of power to a temporarily energizing unit being temporarily energized during use.

### CITATION LIST

### Patent Literature

Patent Literature 1: International Patent Publication No. WO2017/033437
Patent Literature 2: International Patent Publication No. WO2017/159648
Patent Literature 3: International Patent Publication No. WO2021/124789

### SUMMARY OF INVENTION

### Technical Problem

A submarine cable system is a system that includes a land apparatus located on land and a submarine apparatus laid on the seabed, and may have a total length of 10,000 km or more. Since it is difficult to transmit a constant voltage from a power supply apparatus in the land apparatus to the submarine apparatus, the submarine cable system has a power supply system in which a current (referred to as a system current) is supplied through a power supply cable. A power supply circuit acquiring a constant voltage from a system current is disposed inside the submarine apparatus represented by a submarine repeater. The power supply circuit includes, for example, a Zener diode. The power supply circuit acquires a constant voltage by using a breakdown voltage caused by a Zener effect in a case where a voltage is applied between a cathode and an anode of the Zener diode. A multiplication result of the constant voltage and the system current is equivalent to power consumption inside the submarine apparatus. Therefore, the power supply circuit is configured to connect n pieces of Zener diodes in cascade according to the power consumption.

Recently, the submarine cable system is required to include a remote control and response function using an optical signal from a terminal station apparatus in the land apparatus to the submarine apparatus. Therefore, a light source is required on a submarine apparatus side, and for example, there is a case where a laser module is used for the submarine apparatus. The laser module may cause deterioration of abrasiveness for temperature change and long-term continuous use, and thereby lead to a failure. When used in the submarine apparatus that requires 25 years of operation, there is a risk of a failure. It is desirable to stably operate the submarine apparatus including the laser module for a long period of time.

In view of the problem described above, an object of the present disclosure is to provide a submarine apparatus, a submarine cable system, a method for controlling the submarine apparatus, and a non-transitory computer-readable medium that can be stably operated.

### Solution to Problem

A submarine apparatus according to one aspect of the present disclosure includes: a laser element configured to generate an optical signal to be used in a case of responding to a remote control signal received from a land apparatus disposed on land via a cable; and a temperature adjustment means for adjusting a temperature of the laser element, and the submarine apparatus is disposed on the seabed.

A submarine cable system according to one aspect of the present disclosure includes: a land apparatus disposed on land; a submarine apparatus disposed on the seabed; and a cable connecting the land apparatus and the submarine apparatus to each other, wherein the submarine apparatus includes a laser element configured to generate an optical signal to be used in a case of responding to a remote control signal received from the land apparatus via the cable, and a temperature adjustment means for adjusting a temperature of the laser element.

A method for controlling a submarine apparatus according to one aspect of the present disclosure includes: a temperature adjustment step of causing a temperature adjustment means to adjust a temperature of a laser element of a submarine apparatus including the laser element configured to generate an optical signal to be used in a case of responding to a remote control signal received from a land apparatus disposed on land via a cable and the temperature adjustment means for adjusting the temperature of the laser element; and an optical signal generation step of causing the laser element to generate the optical signal.

A non-transitory computer-readable medium according to one aspect of the present disclosure stores a control program for a submarine apparatus, the program causing a computer to execute: a temperature adjustment step of causing a temperature adjustment means to adjust a temperature of a laser element of a submarine apparatus including the laser element configured to generate an optical signal to be used in a case of responding to a remote control signal received from a land apparatus disposed on land via a cable and the temperature adjustment means for adjusting the temperature of the laser element; and an optical signal generation step of causing the laser element to generate the optical signal.

### Advantageous Effects of Invention

According to the present disclosure, it is possible to provide a submarine apparatus, a submarine cable system, a method for controlling the submarine apparatus, and a non-transitory computer-readable medium that can be stably operated.

### BRIEF DESCRIPTION OF DRAWINGS

FIG. 1 is a configuration diagram illustrating a submarine cable system according to a first example embodiment;

FIG. 2 is a block diagram illustrating a submarine apparatus according to the first example embodiment;

FIG. 3 is a flowchart illustrating a method for controlling the submarine apparatus according to the first example embodiment;

FIG. 4 is a circuit diagram illustrating a submarine apparatus according to a second example embodiment;

FIG. 5 is a flowchart illustrating a method for controlling the submarine apparatus according to the second example embodiment;

FIG. 6 is a circuit diagram illustrating a submarine apparatus according to a third example embodiment;

FIG. 7 is a flowchart illustrating a method for controlling the submarine apparatus according to the third example embodiment;

FIG. 8 is a block diagram illustrating a submarine apparatus according to a fourth example embodiment; and

FIG. 9 is a flowchart illustrating a method for controlling the submarine apparatus according to the fourth example embodiment.

### EXAMPLE EMBODIMENT

Hereinafter, example embodiments of the present disclosure will be described in detail with reference to the drawings. In each of the drawings, the same or corresponding elements are denoted by the same reference signs, and redundant descriptions are omitted as necessary for clarity of description.

### First Example Embodiment

A submarine cable system and a submarine apparatus according to a first example embodiment will be described. FIG. 1 is a configuration diagram illustrating the submarine cable system according to the first example embodiment. As illustrated in FIG. 1, a submarine cable system 1 includes a land apparatus 90, a submarine apparatus 10, and a cable CB. Hereinafter, configurations of the <land apparatus>, the <cable>, and the <submarine apparatus> will be described, and then a <method for controlling the submarine apparatus> will be described.

### <Land Apparatus>

The land apparatus 90 is an apparatus disposed on land. The land apparatus 90 is connected to the submarine apparatus 10 by the cable CB. The land apparatus 90 may be connected to another land apparatus 90 by the cable CB. The land apparatus 90 includes, for example, a power supply apparatus, a land terminal station apparatus, and the like. Note that, the land apparatus 90 may include an apparatus other than the power supply apparatus and the land terminal station apparatus as long as an apparatus is disposed on land.

### <Cable>

The cable CB connects the land apparatus 90 and the submarine apparatus 10 to each other, the land apparatuses 90 to each other, and the submarine apparatuses 10 to each other. The cable CB may be disposed on land, or may be disposed on the seabed. The cable CB carries an optical signal including a remote control signal. Further, the cable CB may carry a system current for supplying power to the submarine apparatus 10.

### <Submarine Apparatus>

The submarine apparatus 10 is an apparatus disposed on the seabed. The submarine apparatus 10 is connected to the land apparatus 90 by the cable CB. The submarine apparatus 10 may be connected to another submarine apparatus 10 by the cable CB. The submarine apparatus 10 includes, for example, a submarine repeater and the like. Note that, the submarine apparatus 10 may include an apparatus other than the submarine repeater as long as an apparatus is disposed on the seabed.

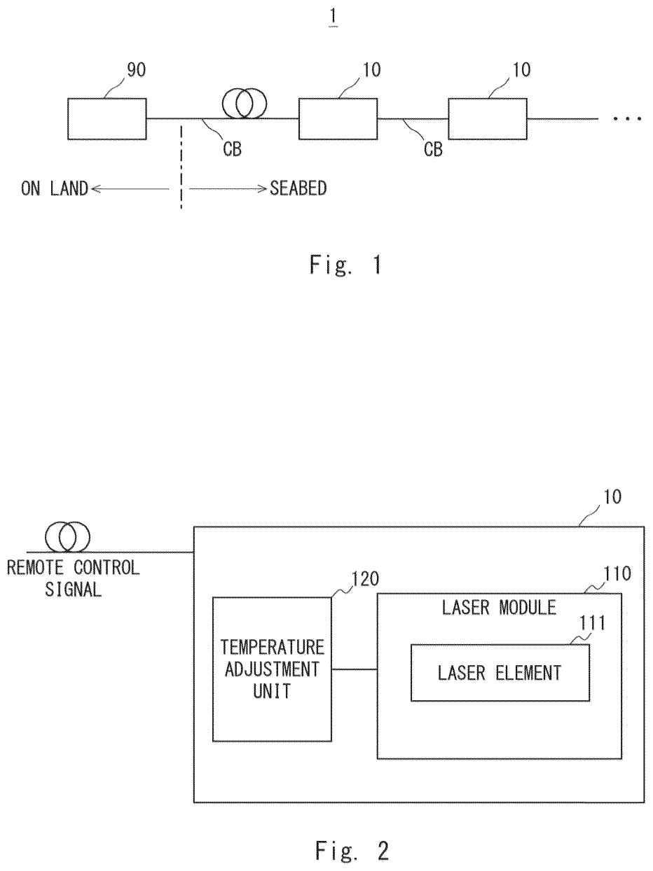

FIG. 2 is a block diagram illustrating the submarine apparatus according to the first example embodiment. As illustrated in FIG. 2, the submarine apparatus 10 includes a laser module 110 and a temperature adjustment unit 120. Each of the laser module 110 and the temperature adjustment unit 120 has a function as a laser light emission means and a temperature adjustment means, respectively. The laser module 110 includes a laser element 111. The laser element 111 has a function as an optical signal generation means. The laser element 111 generates an optical signal to be used in a case of responding to a remote control signal received from the land apparatus 90 disposed on land via the cable CB. The laser element 111 is, for example, a laser diode. In this case, the laser element 111 emits light when a current flows in a forward direction. Note that, the laser element 111 is not limited to a laser diode as long as it generates an optical signal.

A wavelength of laser light generated by the laser element 111 varies depending on a temperature of the laser element 111. By setting the laser element 111 to a predetermined set temperature, the wavelength of the laser light can be set to a predetermined wavelength. The temperature adjustment unit 120 adjusts the temperature of the laser element 111.

### <Method for Controlling Submarine Apparatus>

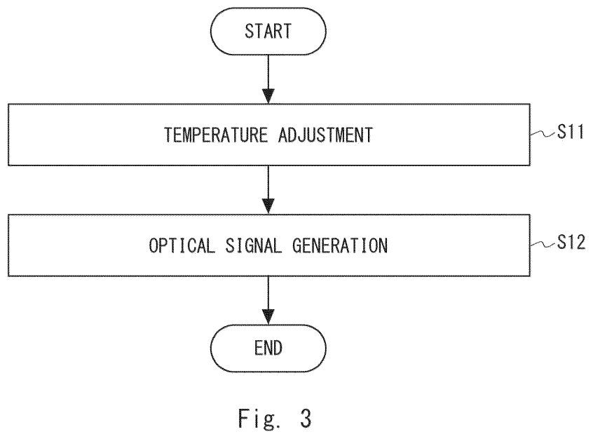

FIG. 3 is a flowchart illustrating a method for controlling the submarine apparatus 10 according to the first example embodiment. As illustrated in FIG. 3, the method for controlling the submarine apparatus 10 includes a temperature adjustment step (step S11) and an optical signal generation step (step S12).

First, as illustrated in step S11, in the temperature adjustment step, the temperature adjustment unit 120 is caused to adjust the temperature of the laser element 111. Next, as illustrated in step S12, in the optical signal generation step, the laser element 111 is caused to generate an optical signal. The optical signal is for use in a case of responding to a remote control signal.

According to the present example embodiment, since the temperature of the laser element 111 can be adjusted, an optical signal can be generated with laser light having a desired wavelength. Therefore, a communication state of the optical signal can be improved. Further, temperature change of the laser element 111 can be suppressed by temperature adjustment in the temperature adjustment unit 120. As a result, consumption of the laser element 111 can be suppressed, and the submarine cable system 1 and the submarine apparatus 10 can be stably operated for a long period of time.

### Second Example Embodiment

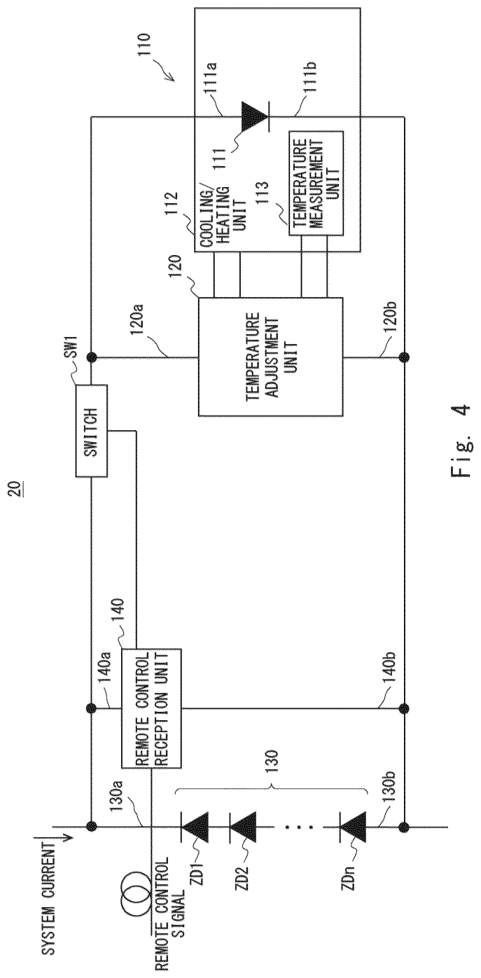

Next, a submarine apparatus according to a second example embodiment will be described. FIG. 4 is a circuit diagram illustrating the submarine apparatus according to the second example embodiment. As illustrated in FIG. 4, a submarine apparatus 20 of the present example embodiment includes a laser module 110, a temperature adjustment unit 120, a constant voltage generation unit 130, a remote control reception unit 140, and a switch SW1. Each of the laser module 110, the temperature adjustment unit 120, the constant voltage generation unit 130, the remote control reception unit 140, and the switch SW1 has a function as a laser light emission means, a temperature adjustment means, a constant voltage generation means, a remote control reception means, and a switch means, respectively. Each of the laser module 110, the temperature adjustment unit 120, and the remote control reception unit 140 is connected in parallel to the constant voltage generation unit 130. Hereinafter, configurations of the <laser module>, the <temperature adjustment unit>, the <constant voltage generation unit>, and the <remote control reception unit> will be described, and then a <method for controlling the submarine apparatus> will be described.

### <Laser Module>

The laser module 110 includes a laser element 111, a cooling/heating unit 112, and a temperature measurement unit 113. Each of the laser element 111, the cooling/heating unit 112, and the temperature measurement unit 113 has a function as an optical signal generation means, a cooling/heating means, and a temperature measurement means, respectively.

The laser element 111 includes an anode 111a and a cathode 111b. The laser element 111 is connected to the constant voltage generation unit 130 via the switch SW1 in such a way that a constant voltage is applied thereto. Specifically, the anode 111a of the laser element 111 is connected to a cathode 130a of the constant voltage generation unit 130 via the switch SW1. The cathode 111b of the laser element 111 is connected to an anode 130b of the constant voltage generation unit 130.

The cooling/heating unit 112 cools and heats the laser element 111 by control in the temperature adjustment unit 120. For example, the cooling/heating unit 112 adjusts the laser element 11 to a predetermined set temperature by a current value flowing from the temperature adjustment unit 120. The temperature measurement unit 113 measures a temperature of the laser element 111. The temperature measurement unit 113 is, for example, a thermistor. In this case, the temperature measurement unit 113 measures the temperature of the laser element 111 from a resistance value of the thermistor. Note that, the temperature measurement unit 113 is not limited to a thermistor as long as it can measure the temperature of the laser element 111. The temperature measurement unit 113 outputs the measured temperature of the laser element 111 to the temperature adjustment unit 120.

### <Temperature Adjustment Unit>

When adjusting the temperature of the laser element 111, the temperature adjustment unit 120 controls the cooling/heating unit 112 in such a way that the temperature of the laser element 111 measured by the temperature measurement unit 113 becomes a predetermined set temperature. For example, the temperature adjustment unit 120 refers to the resistance value of the thermistor, and flows a current through the cooling/heating unit 112 in such a way that the temperature of the laser element 111 becomes the predetermined set temperature. The predetermined set temperature is a temperature at which the laser element 111 generates laser light having a predetermined wavelength.

The temperature adjustment unit 120 has one terminal 120a and the other terminal 120b. The anode 111a and the one terminal 120a are connected to each other. The cathode 111b and the other terminal 120b are connected to each other. The temperature adjustment unit 120 is connected to the constant voltage generation unit 130 via the switch SW1 in such a way that the constant voltage is applied thereto. Specifically, the one terminal 120a of the temperature adjustment unit 120 is connected to the cathode 130a of the constant voltage generation unit 130 via the switch SW1. The other terminal 120b of the temperature adjustment unit 120 is connected to the anode 130b of the constant voltage generation unit 130.

### <Constant Voltage Generation Unit>

The constant voltage generation unit 130 generates a constant voltage. The constant voltage generation unit 130 generates the constant voltage by, for example, a constant current power supply system. In other words, a land apparatus 90 includes a power supply apparatus, and a cable CB includes a power supply cable. The constant voltage generation unit 130 generates the constant voltage by the constant current power supply system using a system current being supplied power from the power supply apparatus via the power supply cable.

The constant voltage generation unit 130 includes, for example, a plurality (n pieces) of Zener diodes ZD1, ZD2, . . . , ZDn disposed in cascade. The plurality of Zener diodes are referred to as a Zener diode ZD. The constant voltage generation unit 130 including the Zener diode ZD includes the cathode 130a and the anode 130b. A system current from the power supply apparatus on land flows into the cathode 130a of the Zener diode ZD. The constant voltage generation unit 130 acquires the constant voltage by using a breakdown voltage caused by a Zener effect when a voltage is applied between the cathode 130a and the anode 130b of the Zener diode ZD. A multiplication result of the acquired constant voltage and the system current is equivalent to power consumption inside the submarine apparatus 20. Therefore, it is configured to connect n pieces of Zener diodes in cascade according to the power consumption. Note that, the constant voltage generation unit 130 is not limited to the Zener diode ZD as long as it can generate the constant voltage.

### <Remote Control Reception Unit>

The remote control reception unit 140 receives a remote control signal transmitted from the land apparatus 90 via the cable CB. The remote control reception unit 140 converts an optical signal being a received remote control signal into an electric signal, and then decodes the acquired electric signal into a control command inside the submarine apparatus 20. For example, the remote control reception unit 140 switches the switch SW1 applying a power supply voltage to the laser element 111.

The remote control reception unit 140 includes one terminal 140a and the other terminal 140b. The remote control reception unit 140 is connected to the constant voltage generation unit 130 in such a way that a constant voltage is applied. Specifically, the one terminal 140a of the remote control reception unit 140 is connected to the cathode 130a of the constant voltage generation unit 130. The other terminal 140b of the remote control reception unit 140 is connected to the anode 130b of the constant voltage generation unit 130.

The remote control reception unit 140 controls on and off of the switch SW1. The switch SW1 connects and disconnects between the cathode 130a and the one terminal 140a, and the anode 111a and the one terminal 120a. For example, when the switch SW1 is on, the switch SW1 connects between the cathode 130a and the one terminal 140a, and the anode 111a and the one terminal 120a. When the switch SW1 is off, the switch SW1 disconnects between the cathode 130a and the one terminal 140a, and the anode 111a and the one terminal 120a.

The remote control reception unit 140 receives the remote control signal transmitted to the submarine apparatus 20 from the land apparatus 90 such as a terminal station apparatus. In a case of responding to the remote control signal, the remote control reception unit 140 turns on the switch SW1, and thereby causes to activate the laser element 111 and the temperature adjustment unit 120. Therefore, since the laser element 111 can be adjusted to a predetermined set temperature, an optical signal of laser light having a predetermined wavelength can be generated.

On the other hand, in a case other than responding to the remote control signal, the remote control reception unit 140 turns off the switch SW1, and thereby causes to stop the laser element 111 and the temperature adjustment unit 120. Therefore, consumption of the laser element 111 can be suppressed.

The submarine apparatus 20 may include a not-illustrated information processing unit having an information processing function including a computer. The information processing unit includes a control unit, a communication unit, and a storage unit that are not illustrated. Each of the control unit, the communication unit, and the storage unit has a function as a control means, a communication means, and a storage means, respectively.

The control unit includes a processor, for example, such as a central processing unit (CPU), a micro processing unit (MPU), an electronic control unit (ECU), a field-programmable gate array (FPGA), and an application specific integrated circuit (ASIC). The control unit has a function as an arithmetic apparatus that performs control processing, arithmetic processing, and the like. Further, the control unit controls an operation of each component such as the communication unit, the storage unit, the laser module 110, the temperature adjustment unit 120, the constant voltage generation unit 130, and the remote control reception unit 140.

Each component of the submarine apparatus 20 can be achieved by, for example, causing a program to be executed by control in the control unit. More specifically, each component may be achieved by the control unit executing a program stored in the storage unit. Further, a necessary program may be recorded in any non-volatile recording medium, installed as necessary, and thereby each component may be achieved. Further, each component is not limited to being achieved by software by a program, and may be achieved by a combination of any of hardware, firmware, and software, and the like.

The communication unit performs communication necessary for the information processing unit to perform information processing. The storage unit is, for example, a read only memory (ROM), a random access memory (RAM), or the like. The storage unit has a function for storing a control program, an arithmetic program, and the like executed by the control unit. Further, the storage unit has a function for temporarily storing processing data and the like.

### <Method for Controlling Submarine Apparatus>

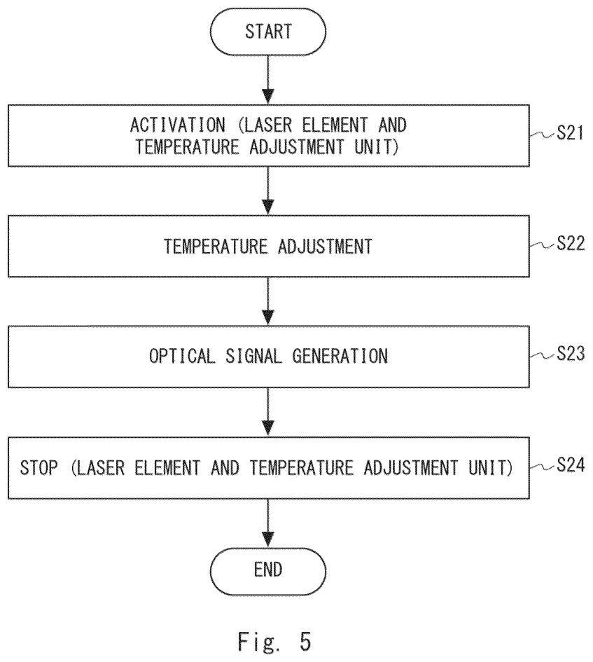

Next, the method for controlling the submarine apparatus 20 according to the present example embodiment will be described. FIG. 5 is a flowchart illustrating the method for controlling the submarine apparatus 20 according to the second example embodiment. As illustrated in FIG. 5, the method for controlling the submarine apparatus 20 of the present example embodiment includes an activation step (step S21), a temperature adjustment step (step S22), an optical signal generation step (step S23), and a stop step (step S24).

First, as illustrated in step S21, in the activation step, the laser element 111 and the temperature adjustment unit 120 are activated. Specifically, in a case of responding to the remote control signal, the remote control reception unit 140 turns on the switch SW1, and thereby causes to activate the laser element 111 and the temperature adjustment unit 120.

Next, as illustrated in step S22, in the temperature adjustment step, the temperature adjustment unit 120 is caused to adjust the temperature of the laser element 111. Next, as illustrated in step S23, in the optical signal generation step, the laser element 111 is caused to generate an optical signal.

Next, as illustrated in step S24, in the stop step, in a case other than responding to the remote control signal, the remote control reception unit 140 turns off the switch SW1, and thereby causes to stop the laser element 111 and the temperature adjustment unit 120.

According to the present example embodiment, in a case other than responding to the remote control signal, the remote control reception unit 140 causes to stop an operation of the laser element 111 and the temperature adjustment unit 120. Therefore, it is possible to suppress progress of deterioration of abrasiveness. As a result, a submarine cable system 1 and the submarine apparatus 20 can be stably operated for a long period of time. Other configurations and effects are included in the description of the first example embodiment.

### Third Example Embodiment

Next, a submarine apparatus according to a third example embodiment will be described. The submarine apparatus 20 according to the second example embodiment causes to stop an operation of the laser element 111 and the temperature adjustment unit 120 in order to suppress progress of deterioration of abrasiveness, in a case other than responding to a remote control signal. However, when the laser module 110 is stopped, a current consumed by the laser module 110 may flow into the constant voltage generation unit 130 that generates a constant voltage. In this case, it is conceivable that the constant voltage generation unit 130 excessively generates heat, and adversely affects long-term reliability of the constant voltage generation unit 130 such as the Zener diode ZD. Therefore, there is a possibility to lead to a failure of the submarine apparatus 20. Thus, the submarine apparatus of the present example embodiment includes a pseudo power supply load unit.

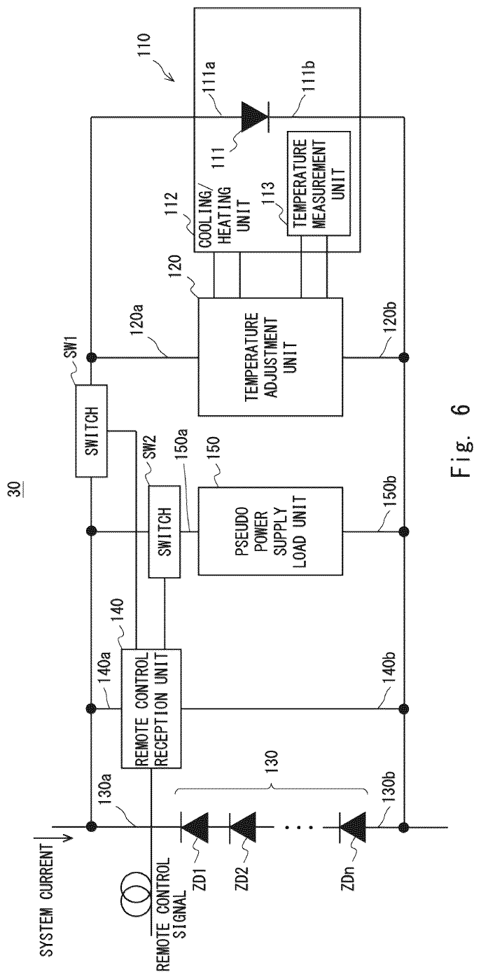

FIG. 6 is a circuit diagram illustrating the submarine apparatus according to the third example embodiment. As illustrated in FIG. 6, a submarine apparatus 30 of the present example embodiment further includes a pseudo power supply load unit 150 and a switch SW2. Each of the pseudo power supply load unit 150 and the switch SW2 has a function as a pseudo power supply load means and a switch means, respectively. Hereinafter, a description will be given of a <method for controlling a submarine apparatus> after a description of the <pseudo power supply load unit>.

### <Pseudo Power Supply Load Unit>

The pseudo power supply load unit 150 is a load that consumes power. For example, the pseudo power supply load unit 150 consumes substantially the same power consumption as power consumption of a laser element 111. The pseudo power supply load unit 150 has one terminal 150a and the other terminal 150b. The pseudo power supply load unit 150 is connected to a constant voltage generation unit 130 via the switch SW2 in such a way that a constant voltage is applied thereto. Specifically, the one terminal 150a of the pseudo power supply load unit 150 is connected to one terminal 140a and a cathode 130a via the switch SW2. The other terminal 150b of the pseudo power supply load unit 150 is connected to the other terminal 140b and an anode 130b.

The switch SW2 is controlled by a remote control reception unit 140. The remote control reception unit 140 controls on and off of the switch SW2. The switch SW2 connects and disconnects between the one terminal 150a, and the one terminal 140a and the cathode 130a. For example, when the switch SW2 is on, the switch SW2 connects between the one terminal 150a, and the one terminal 140a and the cathode 130a. When the switch SW2 is off, the switch SW2 disconnects between the one terminal 150a, and the one terminal 140a and the cathode 130a.

In a case of responding to a remote control signal from a terminal apparatus on land, the remote control reception unit 140 turns on a switch SW1, and thereby cause to activate the laser element 111 and a temperature adjustment unit 120. At the same time, the switch SW2 is turned off, and the pseudo power supply load unit 150 is disconnected from the constant voltage generation unit 130. Therefore, the laser element 111 can be adjusted to a predetermined set temperature, and a sudden change in current and voltage in the constant voltage generation unit 130 can be suppressed.

On the other hand, in a case other than responding to the remote control signal from the terminal apparatus on land, the remote control reception unit 140 turns on the switch SW2, and thereby causes to connect the pseudo power supply load unit 150 to the constant voltage generation unit 130. At the same time, the switch SW1 is turned off, and the laser element 111 and the temperature adjustment unit 120 are stopped. Therefore, consumption of the laser element 111 can be suppressed, also current consumption of the laser module 110 can be suppressed from flowing into the constant voltage generation unit 130, and excessive heat generation of the constant voltage generation unit 130 can be suppressed.

### <Method for Controlling Submarine Apparatus>

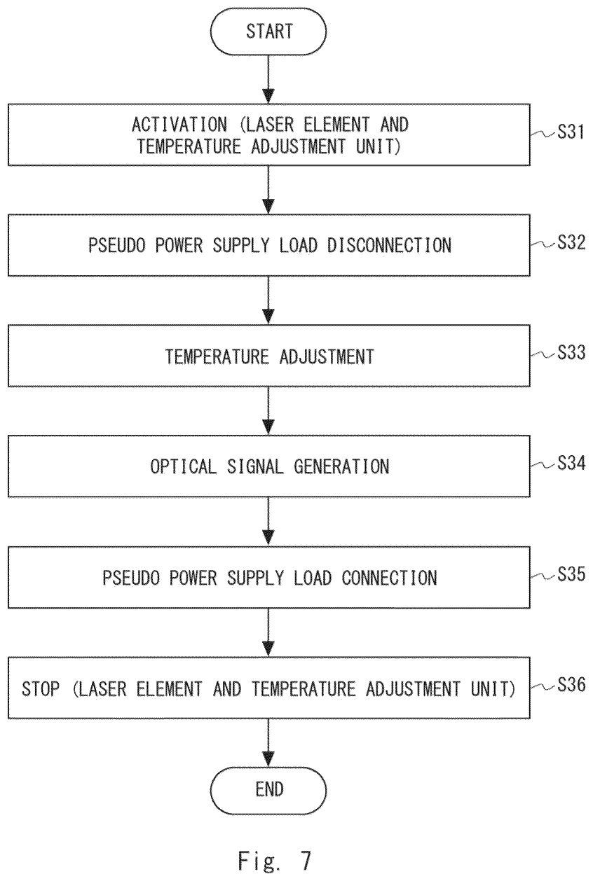

Next, the method for controlling the submarine apparatus 30 according to the present example embodiment will be described. FIG. 7 is a flowchart illustrating the method for controlling the submarine apparatus 30 according to the third example embodiment. As illustrated in FIG. 7, the method for controlling the submarine apparatus 30 of the present example embodiment includes an activation step (step S31), a pseudo power supply load disconnection step (step S32), a temperature adjustment step (step S33), an optical signal generation step (step S34), a pseudo power supply load connection step (step S35), and a stop step (step S36).

First, as illustrated in step S31, in the activation step, the laser element 111 and the temperature adjustment unit 120 are activated. Specifically, in a case of responding to the remote control signal, the remote control reception unit 140 turns on the switch SW1, and thereby causes to activate the laser element 111 and the temperature adjustment unit 120.

Next, as illustrated in step S32, in the pseudo power supply load disconnection step, the pseudo power supply load unit 150 is disconnected from the constant voltage generation unit 130. Specifically, in a case of responding to the remote control signal, the remote control reception unit 140 turns on the switch SW2, and thereby disconnects the pseudo power supply load unit 150 from the constant voltage generating unit 130. Note that, an order of steps S31 and S32 is not limited to this, and may be the same timing.

Next, as illustrated in step S33, in the temperature adjustment step, the temperature adjustment unit 120 is caused to adjust the temperature of the laser element 111. Next, as illustrated in step S34, in the optical signal generation step, the laser element 111 is caused to generate an optical signal.

Next, as illustrated in step S35, in the pseudo power supply load connection step, the pseudo power supply load unit 150 is connected to the constant voltage generation unit 130. Specifically, in a case other than responding to the remote control signal, the remote control reception unit 140 turns off the switch SW2, and thereby causes to connect the pseudo power supply load unit 150 to the constant voltage generation unit 130.

Next, as illustrated in step S36, in the stop step, in a case other than responding to the remote control signal, the remote control reception unit 140 turns off the switch SW1, and causes to stop the laser element 111 and the temperature adjustment unit 120. Note that, an order of steps S35 and S36 is not limited to this, and may be the same timing. In this way, the submarine apparatus 30 is controlled.

According to the present example embodiment, in a case other than responding to the remote control signal, the remote control reception unit 140 causes to connect the pseudo power supply load unit 150 to the constant voltage generation unit 130. Therefore, when the laser module 110 is stopped, a current consumed by the laser module 110 is suppressed from flowing into the constant voltage generation unit 130. As a result, excessive heat generation of the constant voltage generation unit 130 can be suppressed, and a submarine cable system 1 and the submarine apparatus 30 can be stably operated for a long period of time. Other configurations and effects are included in the description of the first and second example embodiments.

### Fourth Example Embodiment

Next, a submarine apparatus according to a fourth example embodiment will be described. In a submarine cable system 1, a wavelength of an optical signal used for remote control from land is determined. The submarine apparatus 30 is required to generate an optical signal having a predetermined wavelength in a case of responding to a remote control signal. The laser module 110 adjusts a temperature of the laser element 111 by the temperature adjustment unit 120, and thereby acquires a desired wavelength.

When power supply is switched from the pseudo power supply load unit 150 to the laser module 110 in a case of responding to the remote control signal, a temperature difference between a set temperature of the laser element 111 being capable of acquiring a desired wavelength and a temperature of the laser element 111 at a time of switching may be large. In this case, in order to eliminate the temperature difference, for example, an excessive current close to a system current may flow. In that case, the constant voltage generation unit 130 including the Zener diode ZD may be difficult to secure a current necessary for maintaining a constant voltage, and it may cause to stop the submarine apparatus 30.

Thus, in the present example embodiment, the temperature adjustment unit 120 is constantly energized as a pseudo power supply load of a constant current power supply system. Thereby, a temperature of the laser element 111 is kept constant.

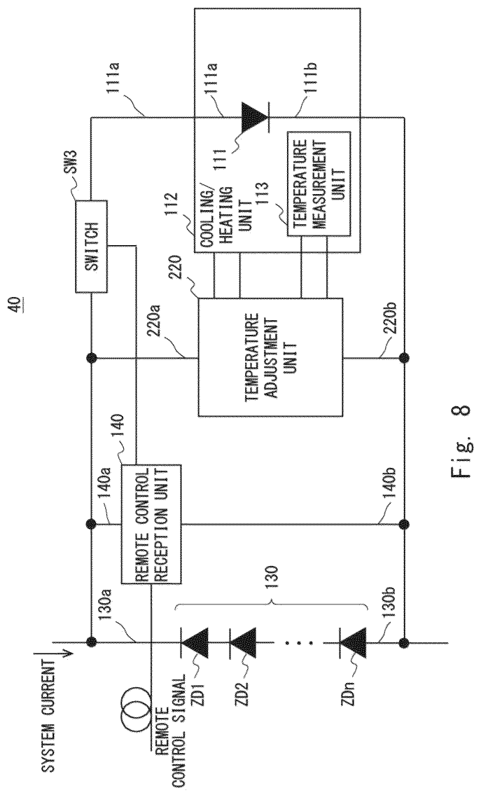

FIG. 8 is a block diagram illustrating a submarine apparatus according to the fourth example embodiment. As illustrated in FIG. 8, a submarine apparatus 40 of the present example embodiment includes a laser module 110, a temperature adjustment unit 220, a constant voltage generation unit 130, a remote control reception unit 140, and a switch SW3. Each of the laser module 110, the temperature adjustment unit 220, the constant voltage generation unit 130, the remote control reception unit 140, and the switch SW3 has a function as a laser light emission means, a temperature adjustment means, a constant voltage generation means, a remote control reception means, and a switch means, respectively. The submarine apparatus 40 of the present example embodiment does not include a pseudo power supply load unit 150.

The laser element 111 is connected to the constant voltage generation unit 130 via the switch SW3 in such a way that a constant voltage is applied thereto. Specifically, an anode 111a of the laser element 111 is connected to a cathode 130a of the constant voltage generation unit 130 via the switch SW3. A cathode 111b of the laser element 111 is connected to an anode 130b of the constant voltage generation unit 130.

The temperature adjustment unit 220 functions as a pseudo power supply load. Specifically, the temperature adjustment unit 220 is configured as a load that consumes power. For example, the temperature adjustment unit 220 may be configured to consume substantially the same power consumption as power consumption of the laser element 111. The temperature adjustment unit 220 has one terminal 220a and the other terminal 220b. The temperature adjustment unit 220 is connected to the constant voltage generation unit 130 in such a way that the constant voltage is applied thereto. Specifically, the one terminal 220a of the temperature adjustment unit 220 is connected to the cathode 130a of the constant voltage generation unit 130. The other terminal 220b of the temperature adjustment unit 220 is connected to the anode 130b of the constant voltage generation unit 130. As described above, the temperature adjustment unit 220 of the present example embodiment is not connected to the constant voltage generation unit 130 via a switch performing connection and disconnection. The temperature adjustment unit 220 is connected to the constant voltage generation unit 130 in such a way that the constant voltage is constantly applied. In other words, the temperature adjustment unit 220 is constantly energized as a pseudo power supply load of the constant current power supply system.

One terminal 140a of the remote control reception unit 140 is connected to the cathode 130a of the constant voltage generation unit 130 and the one terminal 220a of the temperature adjustment unit 220. The other terminal 140b of the remote control reception unit 140 is connected to the anode 130b of the constant voltage generation unit 130 and the other terminal 220b of the temperature adjustment unit 220.

The remote control reception unit 140 controls on and off of the switch SW3. The switch SW3 connects and disconnects between the cathode 130a, the one terminal 140a, and the one terminal 220a, and the anode 111a. For example, when the switch SW3 is on, the switch SW3 connects between the cathode 130a, the one terminal 140a, and the one terminal 220a, and the anode 111a. When the switch SW3 is off, the switch SW3 disconnects between the cathode 130a, the one terminal 140a, and the one terminal 220a, and the anode 111a.

The remote control reception unit 140 receives a remote control signal transmitted to the submarine apparatus 40 from a land apparatus 90 such as a terminal station apparatus. In a case of responding to the remote control signal, the remote control reception unit 140 turns on the switch SW3, and thereby causes to activate the laser element 111. In the present example embodiment, the temperature adjustment unit 220 is constantly applied a power supply voltage. Therefore, the temperature adjustment unit 220 adjusts a temperature of the laser element 111 by flowing a current through a cooling/heating unit 122 in such a way that the laser element 111 can generate an optical signal having a predetermined wavelength. As a result, it is possible to adjust the laser element 111 to a predetermined set temperature when the laser element 111 is activated. Therefore, no significant temperature difference occurs between an actual temperature of the laser element 111 and the predetermined set temperature, and rapid cooling/heating control is not performed from the temperature adjustment unit 220. For this reason, since a sudden current fluctuation does not occur, distribution of the system current does not suddenly change. Thus, a constant voltage acquired by the constant voltage generation unit 130 such as a Zener diode ZD can be maintained. Further, the laser element 111 can generate an optical signal of laser light having a predetermined wavelength.

On the other hand, in a case other than responding to the remote control signal, the remote control reception unit 140 turns off the switch SW3, and thereby causes to stop the laser element 111. Thus, consumption of the laser element 111 can be suppressed. Other configurations are described in first to third example embodiments above.

### <Method for Controlling Submarine Apparatus>

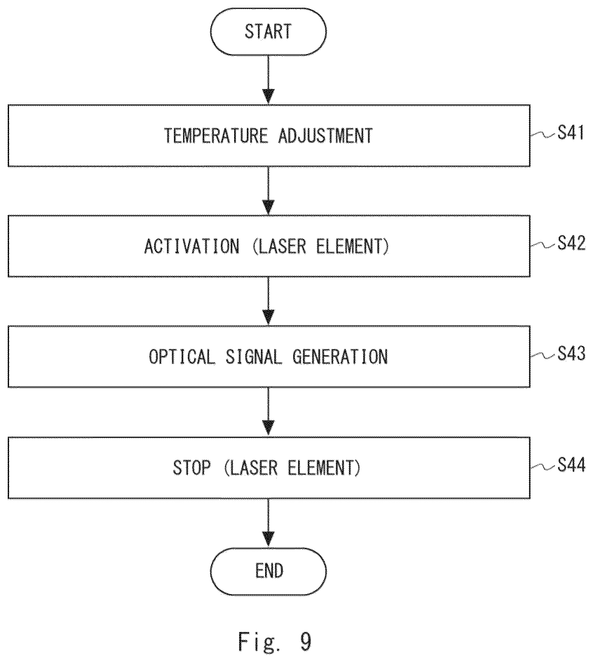

Next, a method for controlling the submarine apparatus 40 according to the present example embodiment will be described. FIG. 9 is a flowchart illustrating the method for controlling the submarine apparatus 40 according to the fourth example embodiment. As illustrated in FIG. 9, the method for controlling the submarine apparatus 40 of the present example embodiment includes a temperature adjustment step (step S41), an activation step (step S42), an optical signal generation step (step S23), and a stop step (step S24).

First, as illustrated in step S41, in the temperature adjustment step, the temperature adjustment unit 120 is caused to adjust the temperature of the laser element 111. Next, as illustrated in step S42, in the activation step, the laser element 111 is activated. Specifically, in a case of responding to the remote control signal, the remote control reception unit 140 turns on the switch SW3, and causes to activate the laser element 111.

Next, as illustrated in step S43, in the optical signal generation step, the laser element 111 is caused to generate an optical signal. The optical signal is for use in a case of responding to the remote control signal received from the land apparatus 90 disposed on land via a cable CB.

Next, as illustrated in step S44, in the stop step, in a case other than responding to the remote control signal, the remote control reception unit 140 turns off the switch SW3, and causes to stop the laser element 111.

According to the present example embodiment, a temperature difference between the temperature of the laser element 111 and a set temperature is eliminated by using, as a pseudo load of the power supply load, the temperature adjustment unit 220, a cooling/heating unit 112, and a temperature measurement unit 113 that control the temperature of the laser element 111. Thus, it is possible to suppress sudden fluctuation of current supply to the cooling/heating unit 112 by the temperature adjustment unit 220 that occurs when the laser element 111 is energized. Therefore, in the constant current power supply system represented by the submarine cable system 1, when power is applied to the laser module 110, it is possible to suppress a sudden current fluctuation that occurs in an attempt to eliminate a temperature difference between the temperature of the laser element 111 and the set temperature, and is possible to maintain the constant voltage acquired by the constant voltage generation unit 130 such as the Zener diode.

Further, the laser module 110 is activated in a state where there is no temperature difference between the temperature of the laser element 111 and the set temperature. Thus, temperature feedback control for the temperature adjustment unit 220 to reach the set temperature of the laser element 111 converges at an early stage. Therefore, a settling time at a time of activation of the laser element 111 can be shortened.

Further, in a case other than responding to the remote control signal, the remote control reception unit 140 causes to stop the laser element 111. Therefore, it is possible to suppress progress of deterioration of abrasiveness. Other configurations and effects are included in the description of the first to third example embodiments.

Note that, the present disclosure is not limited to the above-described example embodiment, and can be appropriately modified without departing from the scope of the present disclosure. For example, it is also possible to combine the configurations of the first to fourth example embodiments.

Further, a control program for a submarine apparatus that causes a computer to read and execute the above-described method for controlling the submarine apparatus is also within the scope of the technical idea of the example embodiment. The control program for the submarine apparatus may be stored in a non-transitory computer-readable medium or a tangible storage medium. By way of example, and not limitation, the computer-readable medium or the tangible storage medium includes a random-access memory (RAM), a read-only memory (ROM), a flash memory, a solid-state drive (SSD), or another memory technique, a CD-ROM, a digital versatile disc (DVD), a Blu-ray (registered trademark) disk, or another optical disk storage, or a magnetic cassette, a magnetic tape, a magnetic disk storage, or another magnetic storage device. The control program for the submarine apparatus may be transmitted on a transitory computer readable medium or a communication medium. By way of example, and not limitation, the transitory computer-readable medium or the communication medium includes a propagation signal in electrical, optical, acoustic, or another form.

Some or all of the above-described example embodiments may be described as the following supplementary notes, but are not limited thereto.

### (Supplementary Note 1)

A submarine apparatus disposed on the seabed, including:
a laser element configured to generate an optical signal to be used in a case of responding to a remote control signal received from a land apparatus disposed on land via a cable; and
a temperature adjustment means for adjusting a temperature of the laser element.

### (Supplementary Note 2)

The submarine apparatus according to supplementary note 1, further including:
a constant voltage generation means for generating a constant voltage;
a remote control reception means for receiving the remote control signal; and
a laser module configured to include the laser element, a cooling/heating means for cooling and heating the laser element, and a temperature measurement means for measuring a temperature of the laser element, wherein
the temperature adjustment means is connected to the constant voltage generation means via a first switch in such a way that the constant voltage is applied, and controls the cooling/heating means in such a way that the temperature measured by the temperature measurement means becomes a predetermined temperature,
the laser element is connected to the constant voltage generation means via the first switch in such a way that the constant voltage is applied, and
the remote control reception means turns on the first switch and thereby causes to activate the laser element and the temperature adjustment means in a case of responding to the remote control signal, and turns off the first switch and thereby causes to stop the laser element and the temperature adjustment means in a case other than responding to the remote control signal.

### (Supplementary Note 3)

The submarine apparatus according to supplementary note 2, further including a pseudo power supply load means for being connected to the constant voltage generation means via a second switch in such a way that the constant voltage is applied, and consuming power,
wherein the remote control reception means turns off the second switch and thereby disconnects the pseudo power supply load means from the constant voltage generation means in a case of responding to the remote control signal, and turns on the second switch and thereby connects the pseudo power supply load means to the constant voltage generation means in a case other than responding to the remote control signal.

### (Supplementary Note 4)

The submarine apparatus according to supplementary note 1, further including:
a constant voltage generation means for generating a constant voltage;
a remote control reception means for receiving the remote control signal; and
a laser module configured to include the laser element, a cooling/heating means for cooling and heating the laser element, and a temperature measurement means for measuring a temperature of the laser element, wherein
the laser element is connected to the constant voltage generation means via a third switch in such a way that the constant voltage is applied,
the temperature adjustment means is connected to the constant voltage generation means, as pseudo power supply load means for consuming power, in such a way that the constant voltage is constantly applied, and controls the cooling/heating means in such a way that the temperature measured by the temperature measurement means becomes a predetermined temperature, and
the remote control reception means turns on the third switch and thereby causes to activate the laser element in a case of responding to the remote control signal, and turns off the third switch and thereby causes to stop the laser element in a case other than responding to the remote control signal.

### (Supplementary Note 5)

The submarine apparatus according to any one of supplementary notes 2 to 4, wherein the constant voltage generation means includes a plurality of Zener diodes.

### (Supplementary Note 6)

The submarine apparatus according to any one of supplementary notes 2 to 5, wherein
the land apparatus includes a power supply apparatus,
the cable includes a power supply cable, and
the constant voltage generation means generates the constant voltage by a constant current power supply system using a current being supplied power from the power supply apparatus via the power supply cable.

### (Supplementary Note 7)

The submarine apparatus according to any one of supplementary notes 1 to 6, wherein a wavelength of laser light generated by the laser element varies depending on the temperature of the laser element.

### (Supplementary Note 8)

A submarine cable system including:
a land apparatus disposed on land;
a submarine apparatus disposed on the seabed; and
a cable connecting the land apparatus and the submarine apparatus to each other,
wherein the submarine apparatus includes
a laser element configured to generate an optical signal to be used in a case of responding to a remote control signal received from the land apparatus via the cable, and
a temperature adjustment means for adjusting a temperature of the laser element.

### (Supplementary Note 9)

The submarine cable system according to supplementary note 8, wherein
the submarine apparatus further includes
a constant voltage generation means for generating a constant voltage,
a remote control reception means for receiving the remote control signal, and
a laser module configured to include the laser element, a cooling/heating means for cooling and heating the laser element, and a temperature measurement means for measuring a temperature of the laser element,
the temperature adjustment means is connected to the constant voltage generation means via a first switch in such a way that the constant voltage is applied, and controls the cooling/heating means in such a way that the temperature measured by the temperature measurement means becomes a predetermined temperature,
the laser element is connected to the constant voltage generation means via the first switch in such a way that the constant voltage is applied, and
the remote control reception means turns on the first switch and thereby causes to activate the laser element and the temperature adjustment means in a case of responding to the remote control signal, and turns off the first switch and thereby causes to stop the laser element and the temperature adjustment means in a case other than responding to the remote control signal.

### (Supplementary Note 10)

The submarine cable system according to supplementary note 9, wherein
the submarine apparatus further includes a pseudo power supply load means for being connected to the constant voltage generation means via a second switch in such a way that the constant voltage is applied, and consuming power, and
the remote control reception means turns off the second switch and thereby disconnects the pseudo power supply load means from the constant voltage generation means in a case of responding to the remote control signal, and turns on the second switch and thereby connects the pseudo power supply load means to the constant voltage generation means in a case other than responding to the remote control signal.

### (Supplementary Note 11)

The submarine cable system according to supplementary note 8, wherein
the submarine apparatus further includes
a constant voltage generation means for generating a constant voltage,
a remote control reception means for receiving the remote control signal, and
a laser module configured to include the laser element, a cooling/heating means for cooling and heating the laser element, and a temperature measurement means for measuring a temperature of the laser element,
the laser element is connected to the constant voltage generation means via a third switch in such a way that the constant voltage is applied,
the temperature adjustment means is connected to the constant voltage generation means, as a pseudo power supply load means for consuming power, in such a way that the constant voltage is constantly applied, and controls the cooling/heating means in such a way that the temperature measured by the temperature measurement means becomes a predetermined temperature, and
the remote control reception means turns on the third switch and thereby causes to activate the laser element in a case of responding to the remote control signal, and turns off the third switch and thereby causes to stop the laser element in a case other than responding to the remote control signal.

### (Supplementary Note 12)

The submarine cable system according to any one of supplementary notes 9 to 11, wherein the constant voltage generation means includes a plurality of Zener diodes.

### (Supplementary Note 13)

The submarine cable system according to any one of supplementary notes 9 to 12, wherein
the land apparatus includes a power supply apparatus,
the cable includes a power supply cable, and
the constant voltage generation means generates the constant voltage by a constant current power supply system using a current being supplied power from the power supply apparatus via the power supply cable.

### (Supplementary Note 14)

The submarine cable system according to any one of supplementary notes 8 to 13, wherein a wavelength of laser light generated by the laser element varies depending on the temperature of the laser element.

### (Supplementary Note 15)

A method for controlling a submarine apparatus, including:
a temperature adjustment step of causing a temperature adjustment means to adjust a temperature of a laser element of a submarine apparatus including the laser element configured to generate an optical signal to be used in a case of responding to a remote control signal received from a land apparatus disposed on land via a cable and the temperature adjustment means for adjusting the temperature of the laser element; and
an optical signal generation step of causing the laser element to generate the optical signal.

### (Supplementary Note 16)

The method for controlling a submarine apparatus according to supplementary note 15, wherein
the submarine apparatus further includes
a constant voltage generation means for generating a constant voltage,
a remote control reception means for receiving the remote control signal, and
a laser module configured to include the laser element, a cooling/heating means for cooling and heating the laser element, and a temperature measurement means for measuring a temperature of the laser element,
the temperature adjustment means is connected to the constant voltage generation means via a first switch in such a way that the constant voltage is applied, and controls the cooling/heating means in such a way that the temperature measured by the temperature measurement means becomes a predetermined temperature, and
the laser element is connected to the constant voltage generation means via the first switch in such a way that the constant voltage is applied,
the method for controlling the submarine apparatus further including:
an activation step of turning on the first switch and thereby causing to activate the laser element and the temperature adjustment means in a case where the remote control reception means responds to the remote control signal; and
a stop step of turning off the first switch and thereby causing to stop the laser element and the temperature adjustment means in a case other than the remote control reception means responds to the remote control signal.

### (Supplementary Note 17)

The method for controlling a submarine apparatus according to supplementary note 16, wherein the submarine apparatus further includes a pseudo power supply load means for being connected to the constant voltage generation means via a second switch in such a way that the constant voltage is applied, and consuming power,
the method for controlling the submarine apparatus, further including:
a pseudo power supply load disconnection step of turning off the second switch and thereby disconnecting the pseudo power supply load means from the constant voltage generation means in a case where the remote control reception means responds to the remote control signal; and
a pseudo power supply load connection step of turning on the second switch and thereby connecting the pseudo power supply load means to the constant voltage generation means in a case other than the remote control reception means responds to the remote control signal.

### (Supplementary Note 18)

The method for controlling a submarine apparatus according to supplementary note 15, wherein
the submarine apparatus further includes
a constant voltage generation means for generating a constant voltage,
a remote control reception means for receiving the remote control signal, and
a laser module configured to include the laser element, a cooling/heating means for cooling and heating the laser element, and a temperature measurement means for measuring a temperature of the laser element,
the laser element is connected to the constant voltage generation means via a third switch in such a way that the constant voltage is applied, and
the temperature adjustment means is connected to the constant voltage generation means, as a pseudo power supply load means for consuming power, in such a way that the constant voltage is constantly applied, and controls the cooling/heating means in such a way that the temperature measured by the temperature measurement means becomes a predetermined temperature,
the method for controlling the submarine apparatus, further including:
a laser element activation step of turning on the third switch and thereby causing to activate the laser element in a case where the remote control reception means responds to the remote control signal; and
a laser element stop step of turning off the third switch and thereby causing to stop the laser element in a case other than the remote control reception means responds to the remote control signal.

### (Supplementary Note 19)

The method for controlling a submarine apparatus according to any one of supplementary notes 16 to 18, wherein the constant voltage generation means includes a plurality of Zener diodes.

### (Supplementary Note 20)

The method for controlling a submarine apparatus according to any one of supplementary notes 16 to 19, wherein
the land apparatus includes a power supply apparatus,
the cable includes a power supply cable, and
the constant voltage generation means generates a constant voltage by a constant current power supply system using a current being supplied power from the power supply apparatus via the power supply cable.

### (Supplementary Note 21)

The method for controlling a submarine apparatus according to any one of supplementary notes 15 to 20, wherein a wavelength of laser light generated by the laser element varies depending on the temperature of the laser element.

### (Supplementary Note 22)

A non-transitory computer-readable medium storing a control program for a submarine apparatus, the program causing a computer to execute:
a temperature adjustment step of causing a temperature adjustment means to adjust a temperature of a laser element of a submarine apparatus including the laser element configured to generate an optical signal to be used in a case of responding to a remote control signal received from a land apparatus disposed on land via a cable and the temperature adjustment means for adjusting the temperature of the laser element; and
an optical signal generation step of causing the laser element to generate the optical signal.

### (Supplementary Note 23)

The non-transitory computer-readable medium storing a control program for a submarine apparatus according to supplementary note 22, wherein
the submarine apparatus further includes
a constant voltage generation means for generating a constant voltage,
a remote control reception means for receiving the remote control signal, and
a laser module configured to include the laser element, a cooling/heating means for cooling and heating the laser element, and a temperature measurement means for measuring a temperature of the laser element,
the temperature adjustment means is connected to the constant voltage generation means via a first switch in such a way that the constant voltage is applied, and controls the cooling/heating means in such a way that the temperature measured by the temperature measurement means becomes a predetermined temperature, and
the laser element is connected to the constant voltage generation means via the first switch in such a way that the constant voltage is applied,
the program further causing the computer to execute:
an activation step of turning on the first switch and thereby causing to activate the laser element and the temperature adjustment means in a case where the remote control reception means responds to the remote control signal; and
a stop step of turning off the first switch and thereby causing to stop the laser element and the temperature adjustment means in a case other than the remote control reception means responds to the remote control signal.

### (Supplementary Note 24)

The non-transitory computer-readable medium storing a control program for a submarine apparatus according to supplementary note 23, wherein the submarine apparatus further includes a pseudo power supply load means for being connected to the constant voltage generation means via a second switch in such a way that the constant voltage is applied, and consuming power,
the program further causing the computer to execute:
a pseudo power supply load disconnection step of turning off the second switch and thereby disconnecting the pseudo power supply load means from the constant voltage generation means in a case where the remote control reception means responds to the remote control signal; and
a pseudo power supply load connection step of turning on the second switch and thereby connecting the pseudo power supply load means to the constant voltage generation means in a case other than the remote control reception means responds to the remote control signal.

### (Supplementary Note 25)

The non-transitory computer-readable medium storing a control program for a submarine apparatus according to supplementary note 22, wherein
the submarine apparatus further includes
a constant voltage generation means for generating a constant voltage,
a remote control reception means for receiving the remote control signal, and
a laser module configured to include the laser element, a cooling/heating means for cooling and heating the laser element, and a temperature measurement means for measuring a temperature of the laser element,
the laser element is connected to the constant voltage generation means via a third switch in such a way that the constant voltage is applied, and
the temperature adjustment means is connected to the constant voltage generation means, as a pseudo power supply load means for consuming power, in such a way that the constant voltage is constantly applied, and controls the cooling/heating means in such a way that the temperature measured by the temperature measurement means becomes a predetermined temperature,
the program further causing the computer to execute:
a laser element activation step of turning on the third switch and thereby causing to activate the laser element in a case where the remote control reception means responds to the remote control signal; and
a laser element stop step of turning off the third switch and thereby causing to stop the laser element in a case other than the remote control reception means responds to the remote control signal.

### (Supplementary Note 26)

The non-transitory computer-readable medium storing a control program for a submarine apparatus according to any one of supplementary notes 23 to 25, wherein the constant voltage generation means includes a plurality of Zener diodes.

### (Supplementary Note 27)

The non-transitory computer-readable medium storing a control program for a submarine apparatus according to any one of supplementary notes 23 to 26, wherein
the land apparatus includes a power supply apparatus,
the cable includes a power supply cable, and
the constant voltage generation means generates a constant voltage by a constant current power supply system using a current being supplied power from the power supply apparatus via the power supply cable.

### (Supplementary Note 28)

The non-transitory computer-readable medium storing a control program for a submarine apparatus according to any one of supplementary notes 22 to 27, wherein a wavelength of laser light generated by the laser element varies depending on the temperature of the laser element.

### REFERENCE SIGNS LIST

1 SUBMARINE CABLE SYSTEM
10, 20, 30, 40 SUBMARINE APPARATUS
90 LAND APPARATUS
110 LASER MODULE
111 LASER ELEMENT
111a ANODE
111b CATHODE
112 COOLING/HEATING UNIT
113 TEMPERATURE MEASUREMENT UNIT
120 TEMPERATURE ADJUSTMENT UNIT
120a, 120b TERMINAL
130 CONSTANT VOLTAGE GENERATION UNIT
130a CATHODE
130b ANODE
140 REMOTE CONTROL RECEPTION UNIT
140a, 140b TERMINAL
150 PSEUDO POWER SUPPLY LOAD UNIT
150a, 150b TERMINAL
220 TEMPERATURE ADJUSTMENT UNIT
220a, 220b TERMINAL
CB CABLE
SW1, SW2, SW3 SWITCH

What is claimed is:

1. A submarine apparatus disposed on the seabed, comprising:
a laser element configured to generate an optical signal to be used in a case of responding to a remote control signal received from a land apparatus disposed on land via a cable; and
temperature adjustment unit configured to adjust a temperature of the laser element.

2. The submarine apparatus according to claim 1, further comprising:
constant voltage generation unit configured to generate a constant voltage;
remote control reception unit configured to receive the remote control signal; and
a laser module configured to include the laser element, cooling/heating unit configured to cool and heat the laser element, and temperature measurement unit configured to measure a temperature of the laser element, wherein
the temperature adjustment unit is connected to the constant voltage generation unit via a first switch in such a way that the constant voltage is applied, and controls the cooling/heating unit in such a way that the temperature measured by the temperature measurement unit becomes a predetermined temperature,
the laser element is connected to the constant voltage generation unit via the first switch in such a way that the constant voltage is applied, and
the remote control reception unit turns on the first switch and thereby causes to activate the laser element and the temperature adjustment unit in a case of responding to the remote control signal, and turns off the first switch and thereby causes to stop the laser element and the temperature adjustment unit in a case other than responding to the remote control signal.

3. The submarine apparatus according to claim 2, further comprising pseudo power supply load unit configured to be connected to the constant voltage generation unit via a second switch in such a way that the constant voltage is applied, and consuming power,
wherein the remote control reception unit turns off the second switch and thereby disconnects the pseudo power supply load unit from the constant voltage generation unit in a case of responding to the remote control signal, and turns on the second switch and thereby connects the pseudo power supply load unit to the constant voltage generation unit in a case other than responding to the remote control signal.

4. The submarine apparatus according to claim 1, further comprising:
constant voltage generation unit configured to generate a constant voltage;
remote control reception unit configured to receive the remote control signal; and
a laser module configured to include the laser element, cooling/heating unit configured to cool and heat the laser element, and temperature measurement unit configured to measure a temperature of the laser element, wherein
the laser element is connected to the constant voltage generation unit via a third switch in such a way that the constant voltage is applied,
the temperature adjustment unit is connected to the constant voltage generation unit, as pseudo power supply load unit configured to consume power, in such a way that the constant voltage is constantly applied, and controls the cooling/heating unit in such a way that the temperature measured by the temperature measurement unit becomes a predetermined temperature, and
the remote control reception unit turns on the third switch and thereby causes to activate the laser element in a case of responding to the remote control signal, and turns off the third switch and thereby causes to stop the laser element in a case other than responding to the remote control signal.

5. The submarine apparatus according to claim 2, wherein the constant voltage generation unit includes a plurality of Zener diodes.

6. The submarine apparatus according to claim 2, wherein
the land apparatus includes a power supply apparatus,
the cable includes a power supply cable, and
the constant voltage generation unit generates the constant voltage by a constant current power supply system using a current being supplied power from the power supply apparatus via the power supply cable.

7. The submarine apparatus according to claim 1, wherein a wavelength of laser light generated by the laser element varies depending on the temperature of the laser element.

8. A submarine cable system comprising:
a land apparatus disposed on land;
a submarine apparatus disposed on the seabed; and
a cable connecting the land apparatus and the submarine apparatus to each other,
wherein the submarine apparatus includes
a laser element configured to generate an optical signal to be used in a case of responding to a remote control signal received from the land apparatus via the cable, and
temperature adjustment unit configured to adjust a temperature of the laser element.

9. The submarine cable system according to claim 8, wherein
the submarine apparatus further includes
constant voltage generation unit configured to generate a constant voltage,
remote control reception unit configured to receive the remote control signal, and
a laser module configured to include the laser element, cooling/heating unit configured to cool and heat the laser element, and temperature measurement unit configured to measure a temperature of the laser element,
the temperature adjustment unit is connected to the constant voltage generation unit via a first switch in such a way that the constant voltage is applied, and controls the cooling/heating unit in such a way that the temperature measured by the temperature measurement unit becomes a predetermined temperature,
the laser element is connected to the constant voltage generation unit via the first switch in such a way that the constant voltage is applied, and
the remote control reception unit turns on the first switch and thereby causes to activate the laser element and the temperature adjustment unit in a case of responding to the remote control signal, and turns off the first switch and thereby causes to stop the laser element and the temperature adjustment unit in a case other than responding to the remote control signal.

10. The submarine cable system according to claim 9, wherein
the submarine apparatus further includes pseudo power supply load unit configured to be connected to the constant voltage generation unit via a second switch in such a way that the constant voltage is applied, and consuming power, and
the remote control reception unit turns off the second switch and thereby disconnects the pseudo power supply load unit from the constant voltage generation unit in a case of responding to the remote control signal, and turns on the second switch and thereby connects the pseudo power supply load unit to the constant voltage generation unit in a case other than responding to the remote control signal.

11. The submarine cable system according to claim 8, wherein
the submarine apparatus further includes
constant voltage generation unit configured to generate a constant voltage,
remote control reception unit configured to receive the remote control signal, and
a laser module configured to include the laser element, cooling/heating unit configured to cool and heat the laser element, and temperature measurement unit configured to measure a temperature of the laser element,
the laser element is connected to the constant voltage generation unit via a third switch in such a way that the constant voltage is applied,
the temperature adjustment unit is connected to the constant voltage generation unit, as pseudo power supply load unit configured to consume power, in such a way that the constant voltage is constantly applied, and controls the cooling/heating unit in such a way that the temperature measured by the temperature measurement unit becomes a predetermined temperature, and
the remote control reception unit turns on the third switch and thereby causes to activate the laser element in a case of responding to the remote control signal, and turns off the third switch and thereby causes to stop the laser element in a case other than responding to the remote control signal.

12. The submarine cable system according to claim 9, wherein the constant voltage generation unit includes a plurality of Zener diodes.

13. The submarine cable system according to claim 9, wherein
the land apparatus includes a power supply apparatus,
the cable includes a power supply cable, and
the constant voltage generation unit generates the constant voltage by a constant current power supply system using a current being supplied power from the power supply apparatus via the power supply cable.

14. The submarine cable system according to claim 8, wherein a wavelength of laser light generated by the laser element varies depending on the temperature of the laser element.

15-21. (canceled)

22. A non-transitory computer-readable medium storing a control program for a submarine apparatus, the program causing a computer to execute:
a temperature adjustment step of causing temperature adjustment unit to adjust a temperature of a laser element of a submarine apparatus including the laser element configured to generate an optical signal to be used in a case of responding to a remote control signal received from a land apparatus disposed on land via a cable and the temperature adjustment unit configured to adjust the temperature of the laser element; and
an optical signal generation step of causing the laser element to generate the optical signal.

23. The non-transitory computer-readable medium storing a control program for a submarine apparatus according to claim 22, wherein
the submarine apparatus further includes
constant voltage generation unit configured to generate a constant voltage,
remote control reception unit configured to receive the remote control signal, and
a laser module configured to include the laser element, cooling/heating unit configured to cool and heat the laser element, and temperature measurement unit configured to measure a temperature of the laser element,
the temperature adjustment unit is connected to the constant voltage generation unit via a first switch in such a way that the constant voltage is applied, and controls the cooling/heating unit in such a way that the temperature measured by the temperature measurement unit becomes a predetermined temperature, and
the laser element is connected to the constant voltage generation unit via the first switch in such a way that the constant voltage is applied,
the program further causing the computer to execute:
an activation step of turning on the first switch and thereby causing to activate the laser element and the temperature adjustment unit in a case where the remote control reception unit responds to the remote control signal; and
a stop step of turning off the first switch and thereby causing to stop the laser element and the temperature adjustment unit in a case other than the remote control reception unit responds to the remote control signal.

24. The non-transitory computer-readable medium storing a control program for a submarine apparatus according to claim 23, wherein the submarine apparatus further includes pseudo power supply load unit configured to be connected to the constant voltage generation unit via a second switch in such a way that the constant voltage is applied, and consuming power,
the program further causing the computer to execute:
a pseudo power supply load disconnection step of turning off the second switch and thereby disconnecting the pseudo power supply load unit from the constant voltage generation unit in a case where the remote control reception unit responds to the remote control signal; and
a pseudo power supply load connection step of turning on the second switch and thereby connecting the pseudo power supply load unit to the constant voltage generation unit in a case other than the remote control reception unit responds to the remote control signal.

25. The non-transitory computer-readable medium storing a control program for a submarine apparatus according to claim 22, wherein
the submarine apparatus further includes constant voltage generation unit configured to generate a constant voltage,
remote control reception unit configured to receive the remote control signal, and
a laser module configured to include the laser element, cooling/heating unit configured to cool and heat the laser element, and temperature measurement unit configured to measure a temperature of the laser element,
the laser element is connected to the constant voltage generation unit via a third switch in such a way that the constant voltage is applied, and
the temperature adjustment unit is connected to the constant voltage generation unit, as pseudo power supply load unit configured to consume power, in such a way that the constant voltage is constantly applied, and controls the cooling/heating unit in such a way that the temperature measured by the temperature measurement unit becomes a predetermined temperature,
the program further causing the computer to execute:
a laser element activation step of turning on the third switch and thereby causing to activate the laser element in a case where the remote control reception unit responds to the remote control signal; and
a laser element stop step of turning off the third switch and thereby causing to stop the laser element in a case other than the remote control reception unit responds to the remote control signal.

26. The non-transitory computer-readable medium storing a control program for a submarine apparatus according to claim 23, wherein the constant voltage generation unit includes a plurality of Zener diodes.

27. The non-transitory computer-readable medium storing a control program for a submarine apparatus according to claim 23, wherein
the land apparatus includes a power supply apparatus,
the cable includes a power supply cable, and
the constant voltage generation unit generates a constant voltage by a constant current power supply system using a current being supplied power from the power supply apparatus via the power supply cable.

28. (canceled)
